(19) United States
(12) Patent Application Publication
(10) Pub. No.: US 2004/0262746 A1
(43) Pub. Date: Dec. 30, 2004

(54) High-density chip scale package and method of manufacturing the same

(75) Inventor: Young-Hee Jung, Daejeon (KR)

Correspondence Address: MORGAN LEWIS & BOCKIUS LLP, 1111 PENNSYLVANIA AVENUE NW, WASHINGTON, DC, 20004, US

(73) Assignee: Samsung Electro-Mechanics Co., Ltd.

(21) Appl. No.: 10/682,081

(22) Filed: Oct. 10, 2003

(30) Foreign Application Priority Data
Jun. 28, 2003 (KR) 2003-42935

(51) Int. Cl. H01L 23/34

(52) U.S. Cl. 257/713

(57) ABSTRACT

Disclosed herein is a high-density chip scale package which is capable of increasing circuit density and expanding a circuit-formable zone. The high-density chip scale package comprises a die having a circuit pattern formed thereon, and a printed circuit board adapted for mounting the die thereon. The printed circuit board has an area 100% to 150% as large as an area of the die, and the printed circuit board has a circuit pattern formed thereon. On the die is mounted a heat sink for radiating heat from the die. Between the printed circuit board and the heat sink is filled an encapsulant for securely connecting the printed circuit board and the heat sink and shielding the printed circuit board from the outside.

### BACKGROUND OF THE INVENTION

1. Field of the Invention

The present invention relates to a high-density chip scale package which is capable of increasing circuit density and expanding a circuit-formable zone, and more particularly to a high-density chip scale package which does not need the provision of a cavity required when a heat sink is attached to the package as in a conventional art, and uses a liquid encapsulant, so that circuit density is increased, a circuit-formable zone is expanded, and heat-radiation efficiency of the heat sink is improved, and which is capable of applying to any one of chips mounted by means of wire bonding and flip-chip technologies.

2. Description of the Related Art

As well known to those skilled in the art, electronic appliances have become smaller while they have gained larger capacities as the electronics industry has become highly developed. Advancement of an IC chip inevitably leads to increase of I/O (input/output) count of a semiconductor. When the I/O count of the semiconductor is increased, there is generated a large amount of heat from an operated IC chip. To eliminate such a larger amount of heat generated from the IC chip, there have been proposed new packages, such as a super BGA (Ball Grid Array) board and an enhanced BGA (E-BGA) board, each of which is obtained by attaching a metal plate serving as a heat sink, for example, a copper plate to a general package. The metal plate is directly attached to the IC chip for radiating heat generated from the IC chip to the outside.

The E-BGA printed circuit board is a new type of BGA printed circuit board different from the conventional BGA printed circuit boards. For example, the E-BGA printed circuit board is a board mainly used in a graphic chip, which is commonly mounted in gaming machines or computers. The E-BGA printed circuit board has a heat sink for radiating heat wholly attached to one side thereof by means of a bonding agent, unlike the conventional BGA printed circuit boards. At the other side of the E-BGA printed circuit board are disposed solder bumps, which are used for mounting chips and connecting with another board or a mother board. At the side of the E-BGA printed circuit board having the disposed solder bumps is also formed a cavity, in which a die is mounted.

The super BGA is an E-BGA having a more complicated structure, in which a plurality of printed circuit boards are stacked to form multiple layers, and a heat sink is attached to the super BGA.

FIGS. 1a and 1b are cross-sectional views showing enhanced BGA (E-BGA) and super BGA (S-BGA) boards, respectively.

Referring to FIG. 1a, a printed circuit board 103 is mounted on a heat sink 101 by means of a boding agent 102. In the middle of the heat sink 101 is formed a cavity, in which a die 104 is mounted. Connection between the printed circuit board 103 and the die 104 is accomplished by a wire 106 connecting a circuit pattern of the die 104 and a wire bonding pad 105 provided on the printed circuit board 103. The wire bonding structure and the die 104 are covered with an epoxy mold compound (EMC) 107 for protecting the wire bonding structure and the circuit pattern of the die 104.

As described above, the E-BGA package has excellent heat-radiation efficiency since the heat sink 101 entirely covers the bottom surface of the package. However, a BGA (Ball Grid Array) technology, which is frequently used at present, is not applicable to mount the E-BGA package to another board. Instead of using the BGA technology, a lead-frame technology using a wire must be adopted to mount the E-BGA package to another board.

The super BGA (S-BGA) board is shown in FIG. 1b. The super BGA has a heat sink 111 attached to the bottom surface of a printed circuit board 112, as in the aforesaid E-BGA. However, the super BGA is different from the E-BGA in that another printed circuit board 114 is stacked on the printed circuit board 112, which features the super BGA. The printed circuit board 114 is attached to the printed circuit board 112 by means of a bonding agent 113. In the middle of the package is formed a cavity, in which a die 115 is mounted. The printed circuit board 112 is electrically connected to the die 115 by means of a wire 119 connected to a wire bonding pad 117. Similarly, the printed circuit board 114 is electrically connected to the die 115 by means of a wire 120 connected to a wire bonding pad 118. The wire bonding structure and the die 115 are covered with an epoxy mold compound (EMC) 116 for protecting the wire bonding structure and a circuit pattern of the die 115.

As described above, the enhanced BGA and super BGA printed circuit boards provide excellent heat-radiation efficiency and high reliability. On the other hand, a process for manufacturing the enhanced BGA printed circuit board or the super BGA printed circuit board is complicated, and formation of a precise circuit pattern is difficult.

A chip scale package (CSP) has also been proposed according to a tendency to make various products lighter, thinner, and smaller in the electronics industry. The chip scale package is a package having a package area nearly equal to an area of a die, which is mounted in the chip scale package. The conventional package has a large package area sufficient to mount several dies therein, whereas the chip scale package has a package area not 150% more than an area of a die mounted in the chip scale package. Also, the chip scale package is mounted to another base board not by using the conventional lead frame but by attaching several solder balls to the bottom surface of the package. That is to say, the chip scale package is mounted to another base board by using a so-called BGA (Ball Grid Array) technology, which is a feature of the chip scale package.

As described above, the process for manufacturing the enhanced BGA printed circuit board or the super BGA printed circuit board is complicated, and formation of the precise circuit pattern is difficult, although the enhanced BGA printed circuit board or the super BGA printed circuit board, which has the heat sink attached to the surface thereof, provides excellent heat-radiation efficiency and high reliability. As a result, it is difficult to apply the enhanced BGA printed circuit board or the super BGA printed circuit board to the chip scale package. Furthermore, the cost of manufacturing the enhanced BGA printed circuit board or the super BGA printed circuit board is increased accordingly. On this account, low-cost boards with excellent thermal performance and reliability have been considered by manufacturing companies with the consequence that a C2BGA (Conduction Cooled Ball Grid Array) has been developed. The C2BGA is a board having a heat sink attached to the surface thereof wherein the heat sink is bonded to the board by means of solder paste, and the heat sink is attached to the board through a reflow process as in a general surface mount technology.

FIGS. 2a to 2j are cross-sectional views showing a process for manufacturing the aforesaid conduction cooled GBA (C2BGA).

FIG. 2a is a cross-sectional view of a copper clad laminate 201 before it is processed. As shown in FIG. 2a, an insulation layer 203 is coated with copper foil 202. Generally, the copper clad laminate is a thin laminate comprising an insulation layer and copper foil thinly coated on the insulation layer, which is a basic raw board used for manufacturing a printed circuit board.

The copper clad laminates are classified into a glass/epoxy copper clad laminate, a heat-resistant resin copper clad laminate, a paper/phenol copper clad laminate, a high-frequency copper clad laminate, a flexible copper clad laminate (polyimide film), and a compound copper clad laminate, on the basis of its use. Among others, the glass/epoxy copper clad laminate is mainly used to manufacture double-sided printed circuit boards and multi-layered printed circuit boards.

The glass/epoxy copper clad laminate is made of a reinforced material obtained by causing epoxy resin (a mixture of resin and a hardening agent) to penetrate into glass fibers, and copper foil. The glass/epoxy copper clad laminates are classified on the basis of the reinforced materials. For example, the glass/epoxy copper clad laminates may be graded into FR-1 to FR-5 on the basis of reinforced materials and thermal resistance, which are prescribed by the NEMA (National Electrical Manufacturers Association). Among the aforesaid five grades, the grade FR-4 is used the most, although demand for the grade FR-5, which has improved glass transient temperature characteristic of resin, is on the increase.

As shown in FIG. 2b, the copper clad laminate 201 is drilled to form via-holes 204, which are required for circuit connection between circuit layers. The copper clad laminate 201 may be drilled, for example, by means of a mechanical drilling method or a laser drilling method.

As shown in FIG. 2c, the copper clad laminate 201 is plated by means of a non-electrolytic copper plating method and an electrolytic copper plating method, to form copper plated layers 205 on the surfaces of the board and inner walls of the via-holes 204. The non-electrolytic copper plating method is carried out first, and then the electrolytic copper plating method is carried out. The reason why the non-electrolytic copper plating method is carried out before the electrolytic copper plating method is carried out is that the electrolytic copper plating method, which requires electricity, cannot be carried out on the insulation layer 203. In other words, the non-electrolytic copper plating method is first carried out to form conductive film required in the electrolytic copper plating method. The non-electrolytic copper plating method is difficult to carry out and is uneconomical, however, a conductive part, which forms a circuit pattern, is preferably formed by means of the electrolytic copper plating method.

As shown in FIG. 2d, paste 206 is filled in the via-holes 206 to protect the non-electrolytic and electrolytic copper plated layers 205 formed on the inner walls of the via-holes 204, and then a circuit pattern is formed by means of etching. Generally, an insulating ink material is used as the paste, although any conductive paste may be used according to the purpose of use of the printed circuit board. The conductive paste is a mixture of at least one metal, such as Cu, Ag, Au, Sn, and Pb, and an organic boding agent. However, the paste filling process as describe above may be omitted according to the purpose of manufacture of the MLB.

As shown in FIG. 2e, through the package is formed a cavity 207, in which a die is mounted. The cavity 207 may be formed, for example, by means of a mechanical drilling method or a punching method.

As shown in FIG. 2f, on the remaining part excluding the part to be connected to another circuit pattern or another board is printed solder resist 208.

As shown in FIG. 2g, the part for circuit connection, such as wires or solder balls, i.e., the part where the solder resist 208 is not applied and thus the copper plated layers 205 are exposed is plated with Ni/Au to form Ni/Au plated layers 209. When the Ni/Au plated layers 209 are formed, the solder resist 208 serves as plating resist. Consequently, the Ni/Au plated layers 209 are formed only on the part where the solder resist 208 is not printed. As will be described later, on the Ni/Au plated layers 209 are formed wire bonding pads, which are provided for wire bonding. Ni plating is carried out first, and then Au plating is carried out. As a result, only the Au plated layers are exposed. The reason why the Ni plating is followed by the Au plating is that oxidization of the exposed copper foil part, which are not covered with the solder resist, is prevented, soldering efficiency of parts to be mounted is improved, and good conductivity is obtained.

Subsequently, at the bottom surface of the package are formed solder balls 210 for directly mounting the package to another base board. The solder balls 210 are used to directly mount the package of the present invention to another board. The solder balls 210 are connected to other solder balls provided at another board so that electrical connection is accomplished between the boards. The board mounted to another board by means of such solder balls 210 is called a BGA (Ball Grid Array) board.

As shown in FIG. 2h, to the bottom surface of the package is attached a heat sink 211.

As shown in FIG. 2i, on the top surface of the heat sink 211 is applied solder paste 213. On the applied solder paste 213 is mounted a die 212. The die 212 is attached to the heat sink 211 by means of a reflow process. Subsequently, on the Ni/Au plated layers 209 are formed bonding pads 214. The bonding pads 214 are connected to a circuit pattern of the die 212 by means of wires 215.

As shown in FIG. 2j, the wire bonding structure and the die 212 are covered with an epoxy mold compound (EMC) 216 for protecting the wire bonding structure and the exposed circuit pattern of the die 212. The epoxy mold compound is a solid material, which is melted by heat. The molten epoxy mold compound is poured into a mold to obtain epoxy mold compound formed in a desired shape, which is finally covered on the package.

As described above, the process for manufacturing the C2BGA is generally similar to the process for manufacturing general boards. According to the process for manufacturing the C2BGA, however, the cavity is formed in the middle of the package, and the heat sink is mounted in the cavity, with the result that the ratio of an effective area necessary for forming solder balls to a total area of the package is reduced, which limits pin count.

International Patent Publication No. WO 02/13586 A1 entitled “ADHESIVE BONDING OF PRINTED CIRCUIT BOARDS TO HEAT SINKS” discloses a structure for efficiently transmitting heat generated from a printed circuit board to a heat sink, wherein a pressure sensitive adhesive layer and a thermosetting adhesive layer are filled in voids defined between the printed circuit board and the heat sink.

Korean Patent Unexamined Publication No.-2001-0009153 entitled “PACKAGE STRUCTURE WITH HIGH HEAT-RADIATION HEAT SPREADER FOR THIN SYSTEM AND METHOD OF MANUFACTURING THE SAME” discloses a structure for improving the heat-radiation efficiency of a chip scale package mounted in a socket of a mother board for computers, wherein a heat sink is disposed on the top of the chip scale package. The heat sink is provided with an inclined surface, at which an air vent and an air slot are formed so that air flow from a cooling fan for cooling the mother board passes through the air vent and then air slot. However, the structure disclosed in the above publication has the cooling fan, which limits its applicable scope.

### SUMMARY OF THE INVENTION

Therefore, the present invention has been made in view of the above problems, and it is an object of the present invention to provide a high-density chip scale package adopting a heat-radiation structure adapted for increasing the ratio of an effective area necessary to form solder balls to a total area of the package and increasing pin count, and a method of manufacturing such a high-density chip scale package.

It is another object of the present invention to provide a high-density chip scale package which does not include a cavity required for mounting a die in a printed circuit board, whereby an effective area necessary to form solder balls is increased and pin count is also increased, and a method of manufacturing such a high-density chip scale package.

It is still another object of the present invention to provide a high-density chip scale package adopting a heat-radiation structure applicable to packages in which a die is mounted by means of wire bonding and flip-chip technologies, and a method of manufacturing such a high-density chip scale package.

It is still another object of the present invention to provide a high-density chip scale package in which a heat sink is attached to the top surface of a die by means of a heat-conductive epoxy bonding agent, thereby improving heat transfer between the die and the heat sink so that heat is smoothly radiated, and a method of manufacturing such a high-density chip scale package.

In accordance with one aspect of the present invention, the above and other objects can be accomplished by the provision of a high-density chip scale package comprising: a die having a circuit pattern formed thereon; a printed circuit board adapted for mounting the die thereon, the printed circuit board having an area 100% to 150.% as large as an area of the die, the printed circuit board having a circuit pattern formed thereon; a heat sink mounted on the die for radiating heat from the die; and an encapsulant filled between the printed circuit board and the heat sink for securely connecting the printed circuit board and the heat sink and shielding the printed circuit board from the outside.

Preferably, the die is attached on the printed circuit board by means of a heat-conductive epoxy bonding agent.

Preferably, the encapsulant is an epoxy-based liquid encapsulant.

Preferably, the printed circuit board includes wire bonding pads so that the die is electrically connected to the printed circuit board by means of wires for connecting the die and the wire bonding pads.

Preferably, the die includes a plurality of solder balls formed at the bottom surface thereof so that the die is electrically connected to the printed circuit board by means of the solder balls.

Preferably, the high-density chip scale package further comprises a liquid encapsulant filled in the space defined between the die and the printed circuit board.

Preferably, the printed circuit board has solder balls formed at the bottom surface thereof for mounting the printed circuit board having the die mounted thereon to another printed circuit board.

In accordance with another aspect of the present invention, there is provided a method of manufacturing a high-density chip scale package comprising the steps of: mounting a die having a circuit pattern formed thereon on a printed circuit board having an area 100% to 150% as large as an area of the die, the printed circuit board having a circuit pattern formed thereon; mounting on the die a heat sink for radiating heat from the die; filling a liquid encapsulant between the printed circuit board and the heat sink; and curing the liquid encapsulant filled between the printed circuit board and the heat sink.

Preferably, the heat sink is attached on the die by means of a heat-conductive epoxy bonding agent at the step of mounting the heat sink on the die.

Preferably, the step of filling the liquid encapsulant comprises removing voids from the filled liquid encapsulant.

Preferably, the step of curing the liquid encapsulant is carried out by means of a thermal curing process.

Preferably, the step of mounting the die on the printed circuit board comprises the steps of: forming wire bonding pads on the printed circuit board; and electrically connecting the die and the wire bonding pads by means of wires.

Preferably, the step of mounting the die on the printed circuit board comprises the steps of: forming a plurality of solder balls at the bottom surface of the die; and electrically connecting the die and the printed circuit board by means of the solder balls.

Preferably, the step of mounting the die on the printed circuit board further comprises the steps of: filling a liquid encapsulant in the space defined between the die and the printed circuit board; and removing voids from the filled liquid encapsulant.

Preferably, the method of manufacturing the high-density chip scale package further comprises forming solder balls at the bottom surface of the printed circuit board thereof so that the printed circuit board having the die mounted thereon is mounted on another printed circuit board.

### BRIEF DESCRIPTION OF THE DRAWINGS

The above and other objects, features and other advantages of the present invention will be more clearly understood from the following detailed description taken in conjunction with the accompanying drawings, in which:

FIGS. 1a and 1b are cross-sectional views showing enhanced BGA (E-BGA) and super BGA (S-BGA) boards, respectively;

FIGS. 2a to 2j are cross-sectional views showing a process for manufacturing a conventional conduction cooled GBA (C2BGA);

FIGS. 3a to 3i are cross-sectional views showing a process for manufacturing a high-density chip scale package adopting a heat-radiation structure, in which a die is mounted on the package by means of a wire bonding technology, according to a preferred embodiment of the present invention; and

FIGS. 4a to 4i are cross-sectional views showing a process for manufacturing a high-density chip scale package adopting a heat-radiation structure, in which a die is mounted on the package by means of a flip-chip technology, according to another preferred embodiment of the present invention.

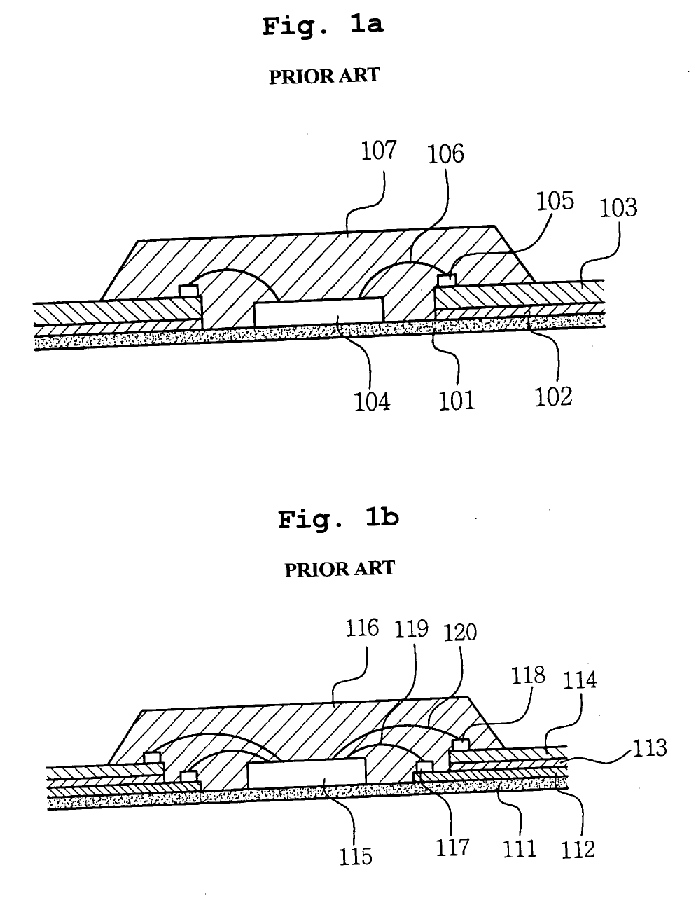

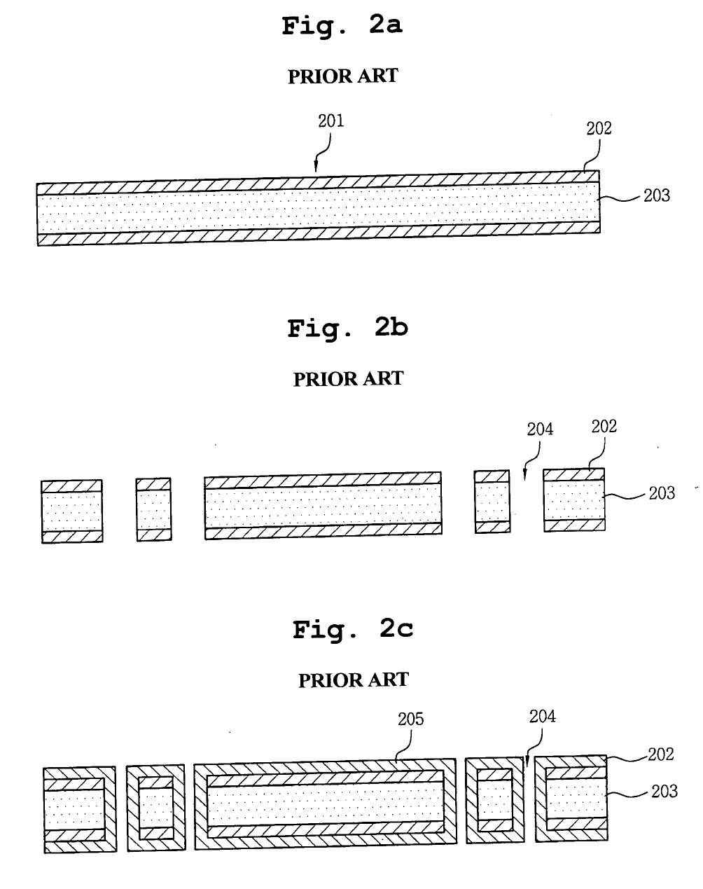

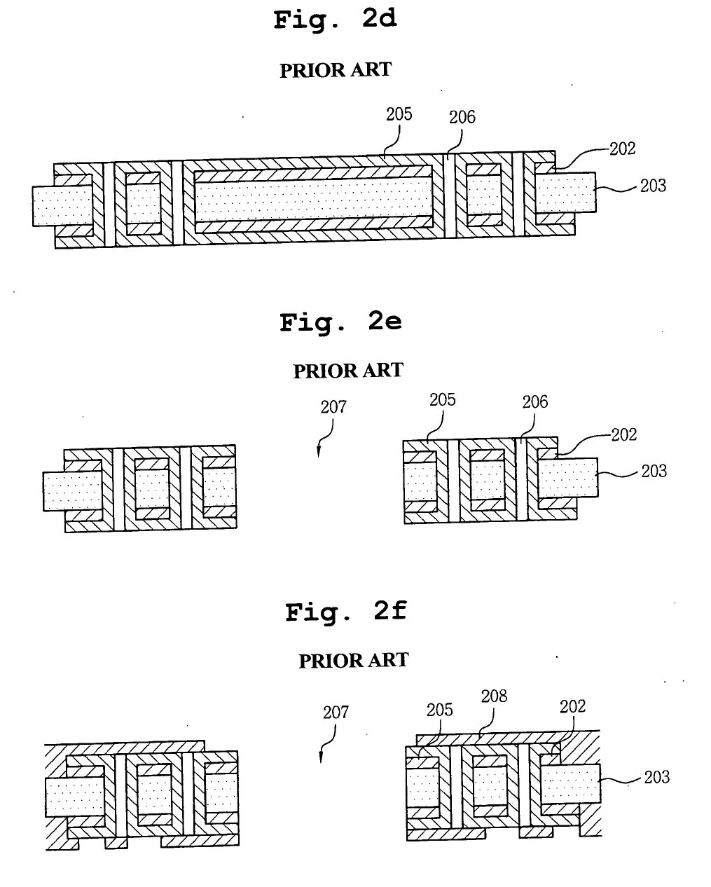

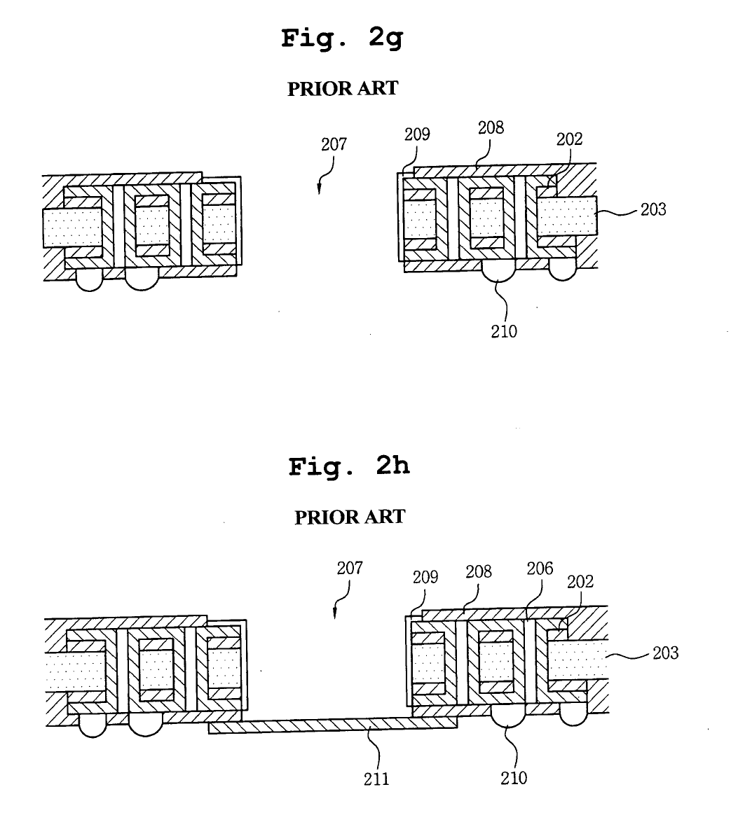

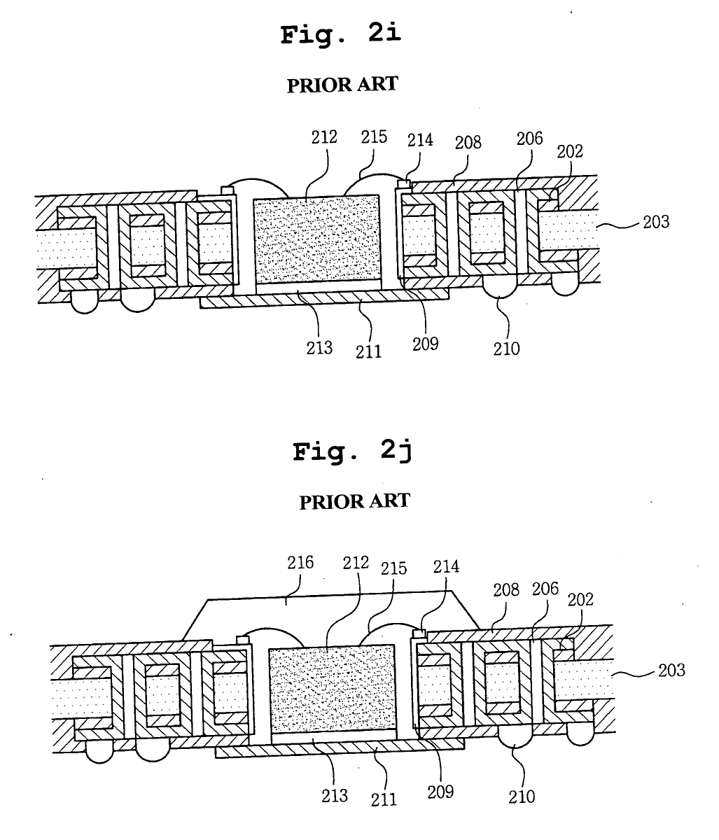

### DESCRIPTION OF THE PREFERRED EMBODIMENTS

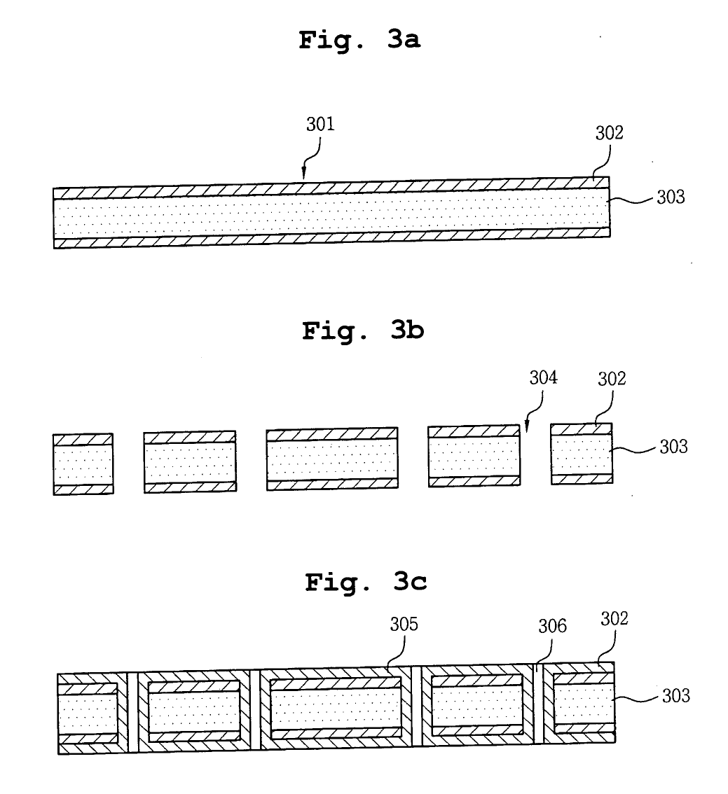

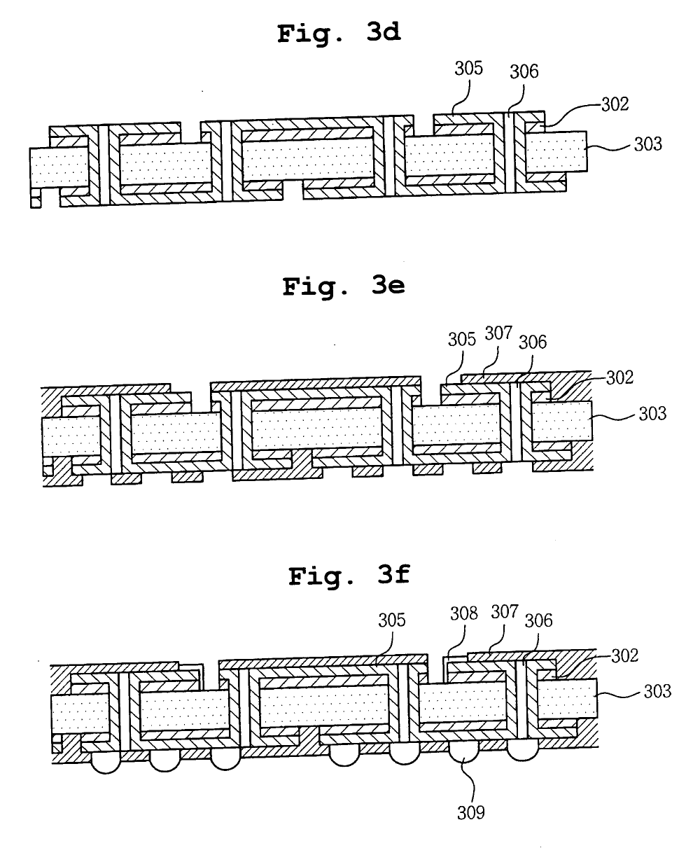

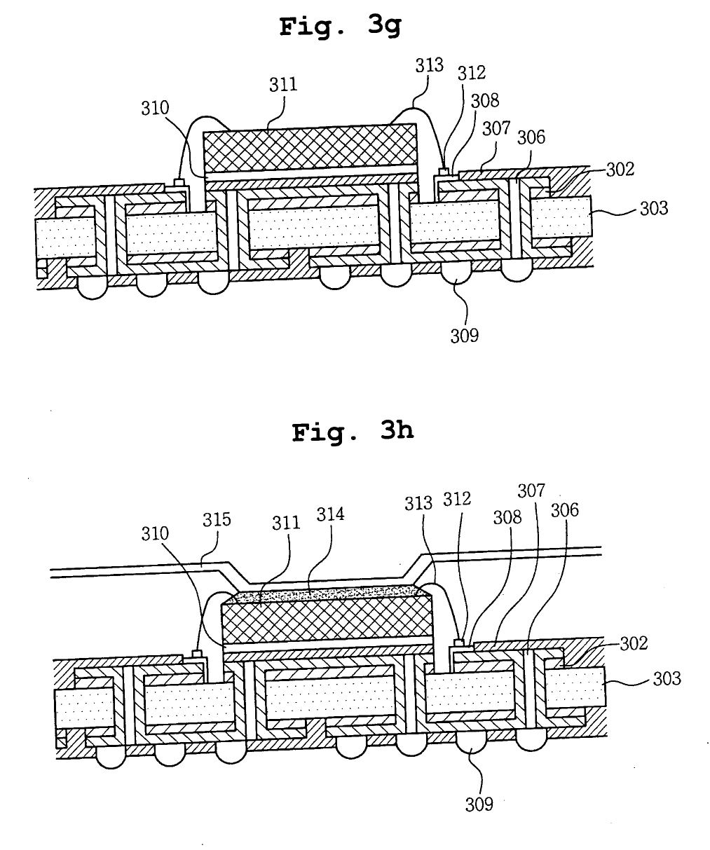

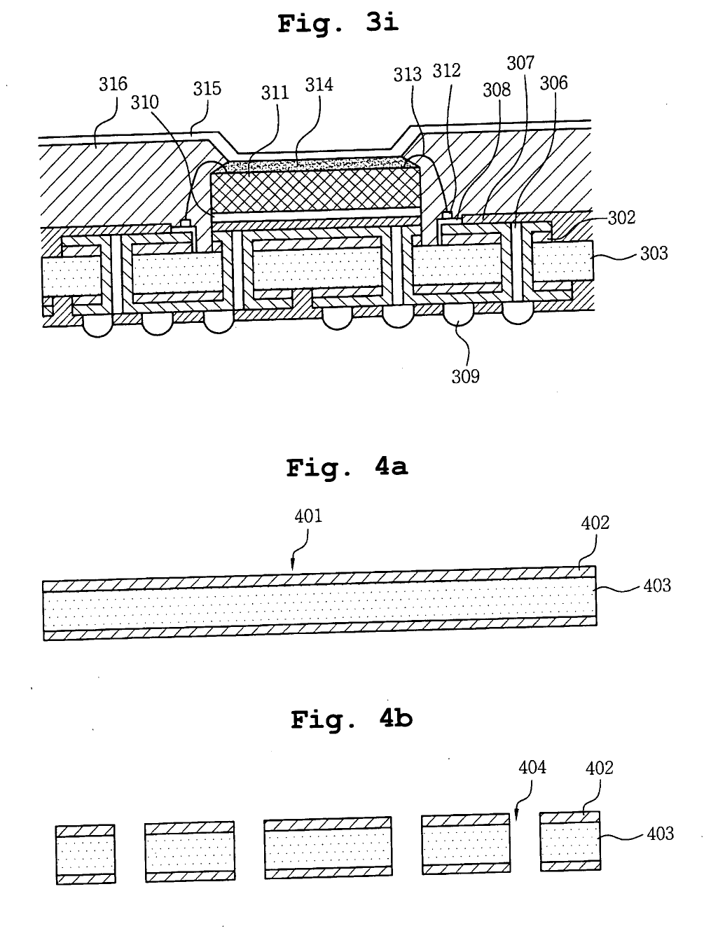

FIGS. 3a to 3i are cross-sectional views showing a process for manufacturing a high-density chip scale package adopting a heat-radiation structure, in which a die is mounted on the package by means of a wire bonding technology, according to a preferred embodiment of the present invention.

FIG. 3a is a cross-sectional view of a copper clad laminate 301, which is a base board for the high-density chip scale package of the present invention. As shown in FIG. 3a, an insulation layer 303 is coated with copper foil 302. There are various kinds of copper clad laminates. However, a glass/epoxy copper clad laminate, which is made of a reinforced material obtained by causing epoxy resin (a mixture of resin and a hardening agent) to penetrate into glass fibers, and copper foil, is mainly used. Especially, a copper clad laminate named FR-4 is the most commonly used. The FR-4 copper clad laminate is used as the copper clad laminate for the present invention, although the present invention is not limited by the kind of the copper clad laminate.

As shown in FIG. 3b, the copper clad laminate 301 is drilled to form via-holes 304, which are required for circuit connection between circuit layers. Although the copper clad laminate 301 may be drilled, for example, by means of a mechanical drilling method or a laser drilling method, the laser drilling method is preferably used when relatively small via-holes are formed.

As shown in FIG. 3c, the copper clad laminate 301 is plated by means of a non-electrolytic copper plating method and an electrolytic copper plating method. Thin copper plated layers are first formed by means of the non-electrolytic copper plating method, and then conductive plated layers 305 are formed on the outside of the board and inner walls of the via-holes 304 by means of the electrolytic copper plating method. Subsequently, insulating paste is filled in the via-holes 306. The plated layers 305 as shown in FIG. 3c include electrolytic plated layers and non-electrolytic plated layers.

As shown in FIG. 3d, in the via-holes 306 is filled paste 306 for protecting the non-electrolytic and electrolytic copper plated layers 305 formed on the inner walls of the via-holes 304, and then a circuit pattern is formed on the plated layers 305 by means of etching. Formation of the circuit pattern by means of etching is accomplished as follows: etching resist, such as dry film, is applied, an etching resist pattern is formed by means of exposure and development, and the remaining part except the circuit pattern is removed by means of an etching solution.

As shown in FIG. 3e, on the remaining part excluding the part to which solder balls and wires are to be connected is printed solder resist 307.

As shown in FIG. 3f, the part for circuit connection, such as the wires or the solder balls, i.e., the part where the solder resist 307 is not applied and thus the copper plated layers 305 are exposed is plated with Ni/Au to form Ni/Au plated layers 308. When the Ni/Au plated layers 308 are formed, the solder resist 307 as shown in FIG. 3e serves as plating resist. Consequently, the Ni/Au plated layers 308 are formed only on the part where the solder resist 307 is not printed. As will be described later, on the Ni/Au plated layers 308 are formed wire bonding pads, which are provided for wire bonding. Ni plating is carried out first, and then Au plating is carried out. As a result, only the Au plated layers are exposed. The reason why the Ni plating is followed by the Au plating is that oxidization of the exposed copper foil part, which are not covered with the solder resist, is prevented, soldering efficiency of parts to be mounted is improved, and good conductivity is obtained.

Subsequently, at the bottom surface of the package are formed solder balls 309 for directly mounting the package to another base board. The solder balls 309 are used to directly mount the package of the present invention to another board. The solder balls 309 are connected to other solder balls provided at another board so that electrical connection is accomplished between the boards. That is to say, the high-density chip scale package of the present invention is mounted on another board by means of a so-called BGA (Ball Grid Array) technology.

As shown in FIG. 3g, on the solder resist layer 307 is applied a bonding agent 310, on which is mounted a die 311. Subsequently, on the Ni/Au plated layers 308 are formed wire bonding pads 312, which are provided for wire bonding. The wire bonding pads 312 are connected to a circuit pattern of the die 311 by means of wires 313 so that the circuit of the die is electrically connected to the circuit of the package. An area of the copper clad laminate 301, which is a base board used in the package of the present invention, is 100% to 150%, preferably 100% to 120%, as large as an area of the die 311 mounted in the package.

As shown in FIG. 3h, on the die 311 is applied an epoxy bonding agent 314, on which is attached a heat sink 315. In the high-density chip scale package of the present invention, the heat sink 315 is directly mounted on the die 311, and the heat sink 315 is securely attached to the die 311 by means of the epoxy bonding agent 314. Consequently, smooth heat radiation is accomplished.

As shown in FIG. 3i, not only on the exposed circuit layers on the package base board between the package base board and the heat sink 315 but also on the solder resist layer 307 is applied a liquid encapsulant 316 for shielding the exposed circuit layers and the solder resist layer 307 from the outside. Subsequently, voids are removed from the liquid encapsulant 316, and the liquid encapsulant 316 is thermally cured by using heat, which is a curing process of the liquid encapsulant 316. The thermally cured encapsulant 316 serves to protect internal circuits from external damaging factors, such as humidity or impact.

The EMC (epoxy mold compound), which is often used to protect the internal circuits from the external damaging factors, is a solid, not a liquid. Consequently, physical impact is given to the package when the EMC is applied to the package. On the other hand, such physical impact is avoidable when the liquid encapsulant is used.

As described above, the chip scale package (CSP) provided for satisfying miniaturization of the package is characterized in that an area of the package is 100% to 150% as large as an area of the die (chip) mounted thereon, and in that the high-density chip scale package is directly mounted on another board by means of the solder balls 309. With the high-density chip scale package of the present invention as shown in FIGS. 3a to 3h, packages can be manufactured with high density and downsized without reduction of heat-radiation efficiency.

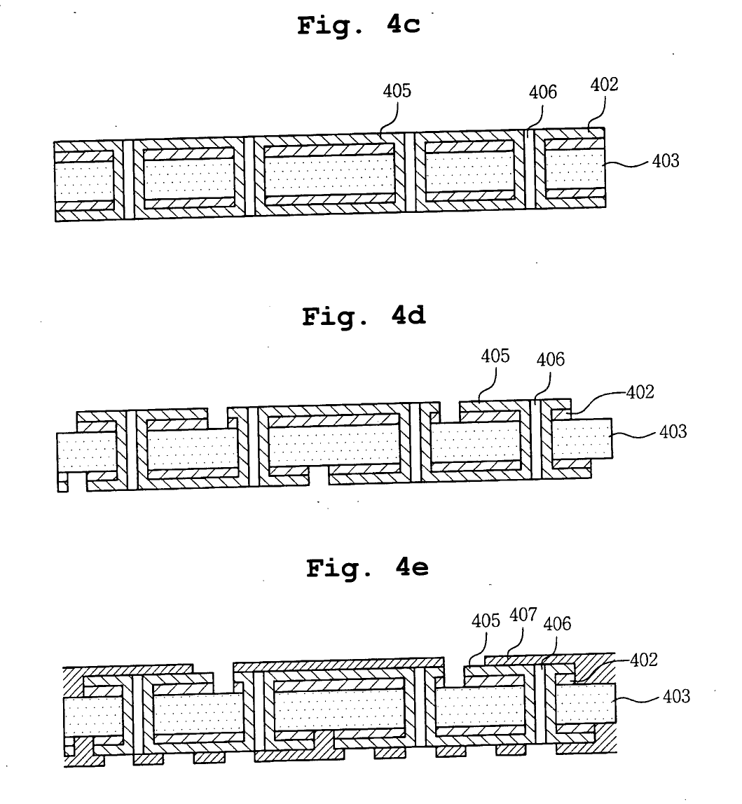

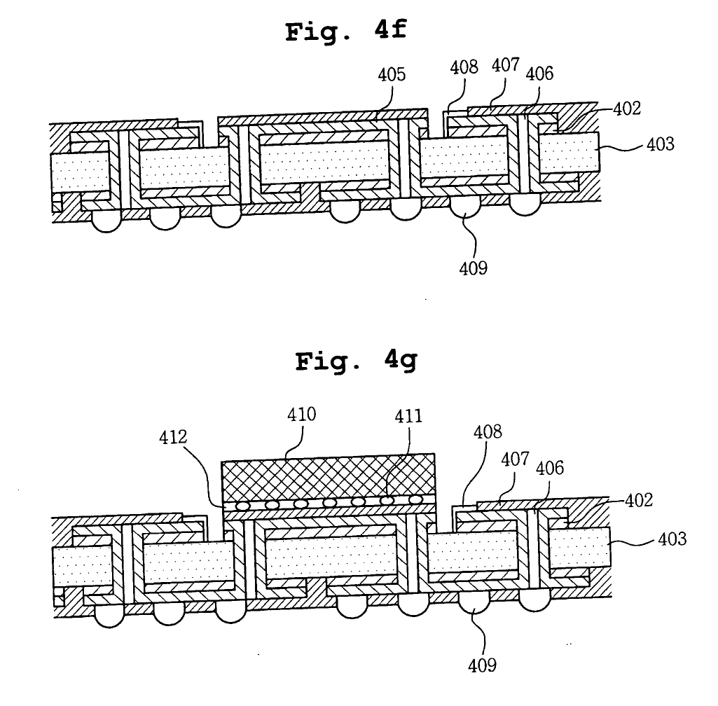

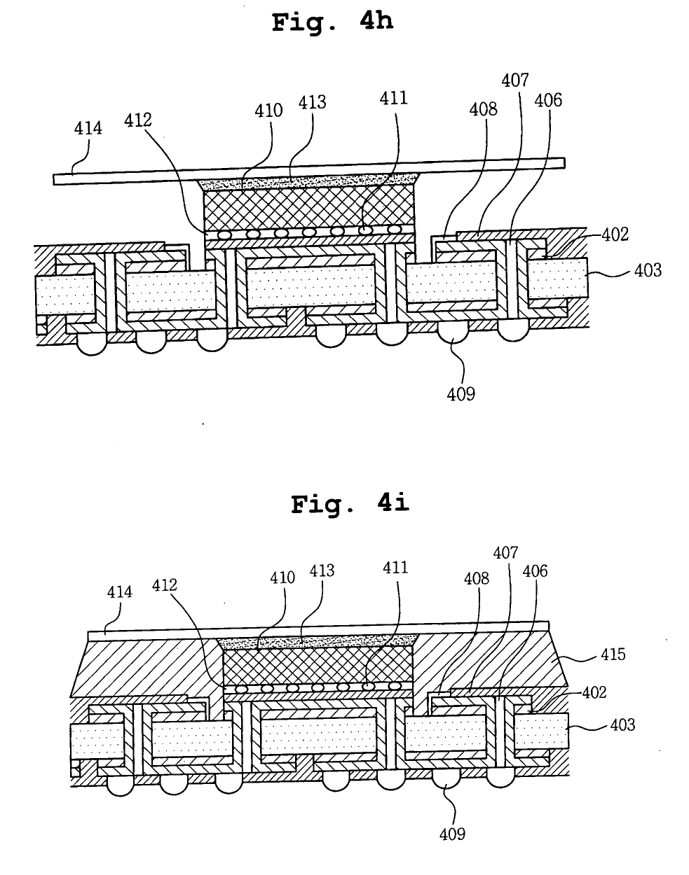

FIGS. 4a to 4i are cross-sectional views showing a process for manufacturing a high-density chip scale package adopting a heat-radiation structure, in which a die is mounted on the package by means of a flip-chip technology, according to another preferred embodiment of the present invention.

FIG. 4a is a cross-sectional view of a copper clad laminate 401, which is a base board for the high-density chip scale package of the present invention. The board used in this embodiment of the present invention is identical to the board as shown in FIG. 3a. Consequently, a copper clad laminate named FR-4 is used as the copper clad laminate for the present invention, although the present invention is not limited by the aforesaid copper clad laminate. As shown in FIG. 4a, an insulation layer 403 is coated with copper foil 402.

As shown in FIG. 4b, the copper clad laminate 401 is drilled to form via-holes 404, which are required for circuit connection between circuit layers. Although the copper clad laminate 401 may be drilled, for example, by means of a mechanical drilling method or a laser drilling method, the laser drilling method is preferably used when relatively small via-holes are formed.

As shown in FIG. 4c, the copper clad laminate 401 is entirely plated by means of a non-electrolytic copper plating method and an electrolytic copper plating method. Thin copper plated layers are first formed by means of the non-electrolytic copper plating method, and then conductive plated layers 405 are formed on the outside of the board and inner walls of the via-holes 404 by means of the electrolytic copper plating method. Subsequently, insulating paste 406 is filled in the via-holes 406. The plated layers 405 as shown in FIG. 4c include electrolytic plated layers and non-electrolytic plated layers.

As shown in FIG. 4d, a circuit pattern is formed on the conductive plated layers 405 surrounding the board by means of etching. Formation of the circuit pattern by means of etching is accomplished as follows: etching resist, such as dry film, is applied, an etching resist pattern is formed by means of exposure and development, and the remaining part except the circuit pattern is removed by means of an etching solution.

As shown in FIG. 4e, on the remaining part excluding the part to which solder balls and wires are to be connected, i.e., on the remaining part excluding the part in which solder ball pads and wire bonding pads are formed for circuit connection is printed solder resist 407, which protects the circuit pattern formed on the plated layers 405.

As shown in FIG. 4f, the part for circuit connection, such as the wires or the solder balls, i.e., the part where the solder resist 407 is not applied and thus the copper plated layers 405 are exposed is plated with Ni/Au to form Ni/Au plated layers 408. When the Ni/Au plated layers 408 are formed, the solder resist 407 as shown in FIG. 4e serves as plating resist. Consequently, the Ni/Au plated layers 408 are formed only on the part where the solder resist 407 is not printed. Ni plating is carried out first, and then Au plating is carried out. As a result, only the Au plated layers are exposed. The reason why the Ni plating is followed by the Au plating is that oxidization of the exposed copper foil part, which are not covered with the solder resist, is prevented, soldering efficiency of parts to be mounted is improved, and good conductivity is obtained.

Subsequently, at the bottom surface of the package are formed solder balls 409 for directly mounting the package to another base board. The solder balls 409 are used to directly mount the package of the present invention on another board. The solder balls 409 are connected to other solder balls provided at another board so that electrical connection is accomplished between the package of the present invention and the other board. That is to say, the high-density chip scale package of the present invention is mounted on another board by means of a so-called BGA (Ball Grid Array) technology.

As shown in FIG. 4g, on the solder resist layer 407 is mounted a die 410 having solder balls 411 formed at the bottom surface thereof. Between the die 410 and the solder resist layer 407, i.e., in the space where the solder balls 411 are not disposed is filled a liquid under-filling encapsulant 412, which is thermally cured to securely connect the die 410 and the solder resist layer 407. An area of the copper clad laminate 401, which is a base board used in the package of the present invention, is 100% to 150%, preferably 100% to 120%, as large as an area of the die 410 mounted in the package.

As shown in FIG. 4h, on the die 410 is applied an epoxy bonding agent 413, on which is attached a heat sink 414. In the high-density chip scale package of the present invention, the heat sink 414 is directly mounted on the die 410, and the heat sink 414 is securely attached to the die 410 by means of the epoxy bonding agent 413, in the same manner as the process described with reference to FIGS. 3a to 3i. Consequently, smooth heat radiation is accomplished.

As shown in FIG. 4i, not only on the exposed circuit layers on the package base board between the package base board and the heat sink 414 but also on the solder resist layer 407 is applied a liquid encapsulant 316 for shielding the exposed circuit layers and the solder resist layer 407 from the outside. Subsequently, voids are removed from the liquid encapsulant 415, and the liquid encapsulant 415 is thermally cured by using heat, which is a curing process of the liquid encapsulant 415. Preferably, the liquid encapsulant 415 is an epoxy-based liquid encapsulant.

The thermally cured encapsulant 415 serves to protect internal circuits from external damaging factors, such as humidity or impact. The liquid encapsulant 415 filled in the space defined between the heat sink 414 and the package may be the same as the liquid under-filling encapsulant 412 described with reference to FIG. 4h.

As apparent from the above description, the present invention provides a high-density chip scale package adopting a heat-radiation structure adapted for increasing the ratio of an effective area necessary to form solder balls to a total area of the package and increasing pin count without reduction of heat-radiation efficiency.

The high-density chip scale package of the present invention does not include a cavity required for mounting a die in a printed circuit board, whereby an effective area necessary to form solder balls is increased and pin count is also increased.

Furthermore, the present invention provides a high-density chip scale package adopting a heat-radiation structure applicable to packages in which a die is mounted by means of wire bonding and flip-chip technologies without reduction of heat-radiation efficiency.

Also, a heat sink is attached to the top surface of a die by means of a heat-conductive epoxy bonding agent, with the result that heat transfer between the die and the heat sink, and thus heat is smoothly radiated.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A high-density chip scale package comprising:
a die having a circuit pattern formed thereon;
a printed circuit board adapted for mounting the die thereon, the printed circuit board having an area 100% to 150% as large as an area of the die, the printed circuit board having a circuit pattern formed thereon;
a heat sink mounted on the die for radiating heat from the die; and
an encapsulant filled between the printed circuit board and the heat sink for securely connecting the printed circuit board and the heat sink and shielding the printed circuit board from the outside.

2. The package as set forth in claim 1, wherein the die is attached on the printed circuit board by means of a heat-conductive epoxy bonding agent.

3. The package as set forth in claim 1, wherein the encapsulant is an epoxy liquid encapsulant.

4. The package as set forth in claim 1, wherein the printed circuit board includes wire bonding pads so that the die is electrically connected to the printed circuit board by means of wires for connecting the die and the wire bonding pads.

5. The package as set forth in claim 1, wherein the die includes a plurality of solder balls formed at the bottom surface thereof so that the die is electrically connected to the printed circuit board by means of the solder balls.

6. The package as set forth in claim 5, further comprising a liquid encapsulant filled in the space defined between the die and the printed circuit board.

7. The package as set forth in claim 1, wherein the printed circuit board has solder balls formed at the bottom surface thereof for mounting the printed circuit board having the die mounted thereon to another printed circuit board.
